(19) United States
(12) Patent Application Publication
(10) Pub. No.: US 2012/0273643 A1
(43) Pub. Date: Nov. 1, 2012

(54) DOCKING STATION

(76) Inventor: Cheng-Chun CHANG, New Taipei City (TW)

(21) Appl. No.: 13/164,871

(22) Filed: Jun. 21, 2011

(30) Foreign Application Priority Data
Apr. 28, 2011 (TW) 100207506

(51) Int. Cl. H05K 7/12

(52) U.S. Cl. 248/346.06

(57) ABSTRACT

The present invention relates to an improved docking station, which comprises a slide member, the top surface thereof is longitudinally formed with an accommodation slot allowing a connector plug to be positioned and to protrude, two opposite ends of the bottom of the accommodation slot are installed a pair of block sheets, a pair of fins are left/right extended from the slide member and a resilient unit is installed at the front; and a fasten member, a platform defined on the top surface thereof is installed with a slide groove having a width larger than the accommodation slot, the left and right lateral walls thereof are formed with a pair of rails for receiving the left and right fins, the inner wall of the front end of the fasten member is protrudingly formed with a positioning part, so the accommodation slot is enabled to elastically forward/backward slide with the slide member below the slide groove of the fasten member; so a connector socket at the bottom of a hand-held device having at least two different widths can be rapidly and conveniently inserted in the connector plug protruded from the slide member and the top surface of the fasten member, and the back board of each hand-held device is leaned against a base having the fasten member, for processing operations of charging or data transferring.

### BACKGROUND OF THE INVENTION

1. Field of the Invention

The present invention relates to a docking station, especially to a docking station allowing at least two hand-held devices to be processed with charging or data transferring operations, e.g. a tablet PC, intelligent mobile phone or media displayer.

2. Description of Related Art

With the development of technology, 3C electronic products are designed to be thinner and smaller and a trend of touch control is also raising; so the 3C electronic products, for example hand-held devices e.g. a tablet PC, intelligent mobile phone and media displayer, become necessary items in our life. In fact, take a tablet PC, e.g. the iPad, an intelligent mobile phone, e.g. the iPhone or a media displayer, e.g. the iPod for instances, the tablet PC, intelligent mobile phone and media displayer have their own charging stands and transmission cables for processing operations of charging or data transferring to the mentioned hand-held devices; a hand-held device has its own charging stand, has been adopted in the market for years; in other words, different hand-held devices may not be able to share the same peripheral products, e.g. the charge base.

In view of the abovementioned shortage, manufacturers have developed a general charge docking station capable of being used with plural types of hand-held devices, the top of the docking station is installed with a groove having the length and width greater than all of the hand-held devices to be mated, the central bottom of the groove is protrudingly installed with a connector plug, the docking station is further installed with plural insertion cover boards, the top of each cover board is formed with an accommodation groove corresponding to the size and appearance of each type of hand-held device, the bottom of the accommodation groove has a through hole. When a hand-held device is desired to be charged, a user has to pick the insertion cover board in which the accommodation groove having the same appearance and size of the hand-held device to be charged, then the insertion cover board is disposed on the groove on the top of the docking station, such that the connector plug is enabled to protrude from the through hole, then the connector insertion groove at the bottom of the hand-held device is aimed to the connector plug in the accommodation groove and is inserted therein, so the bottom of the hand-held device is positioned in the accommodation groove for being processed with the charging operation.

However, before the mentioned docking station is processed with the charging operation, a processing of mating the hand-held device with an insertion cover board has to be done such that the insertion cover board is enabled to be combined in the groove at the top of the docking station; as a result, different hand-held devices have to be mated with insertion cover boards in which the accommodation groove having the mated appearance, so it is not convenient in use. If one of the insertion cover boards is lost, the hand-held device mated with the lost insertion cover board can not be charged. As such, how to improve the docking station to be capable of being used with at least two types of hand-held devices having different sizes without utilizing insertion cover boards shall be developed.

### SUMMARY OF THE INVENTION

One primary object of the present invention is to provide an improved docking station, in which a slide member capable of elastically forward/backward sliding is installed in a fasten member, so a connector socket at the bottom of a hand-held device having at least two different widths, e.g. a tablet PC and intelligent mobile phone, can be rapidly and conveniently inserted in a connector plug protruded from the slide member and the top surface of the fasten member, for processing operations of charging or data transferring. Thus, the docking station provided by the present invention can be shared by different hand-held devices, and more convenience is provided to a user for overcoming the mentioned disadvantages and inconvenience of the conventional arts.

For achieving the mentioned object, one solution of the present invention is to provide an improved docking station, which comprises:

a slide member, the top surface thereof is longitudinally formed with an accommodation slot allowing a connector plug to be positioned and to protrude, two opposite ends of the bottom of the accommodation slot are installed with a pair of block sheets, a pair of fins are left/right extended from the slide member and a resilient unit is installed at the front; and

a fasten member, a platform defined on the top surface thereof is installed with a slide groove having a width larger than the accommodation slot, the left and right lateral walls thereof are formed with a pair of rails for receiving the left and right fins, the inner wall of the front end of the fasten member is protrudingly formed with a positioning part, so the accommodation slot is enabled to elastically forward/backward slide with the slide member below the slide groove of the fasten member.

### BRIEF DESCRIPTION OF THE DRAWINGS

FIG. 1 is a perspective exploded view illustrating the docking station, according to the present invention;

FIG. 2 is another perspective exploded view illustrating the docking station taken from another angle, according to the present invention;

FIG. 3 is a perspective view illustrating the assembly of the docking station, according to the present invention;

FIG. 4 is a cross sectional view illustrating the docking station being connected to a hand-held device, according to the present invention; and

FIG. 5 is a cross sectional view illustrating the docking station being connected to another hand-held device, according to the present invention.

### DETAILED DESCRIPTION OF THE PREFERRED EMBODIMENT

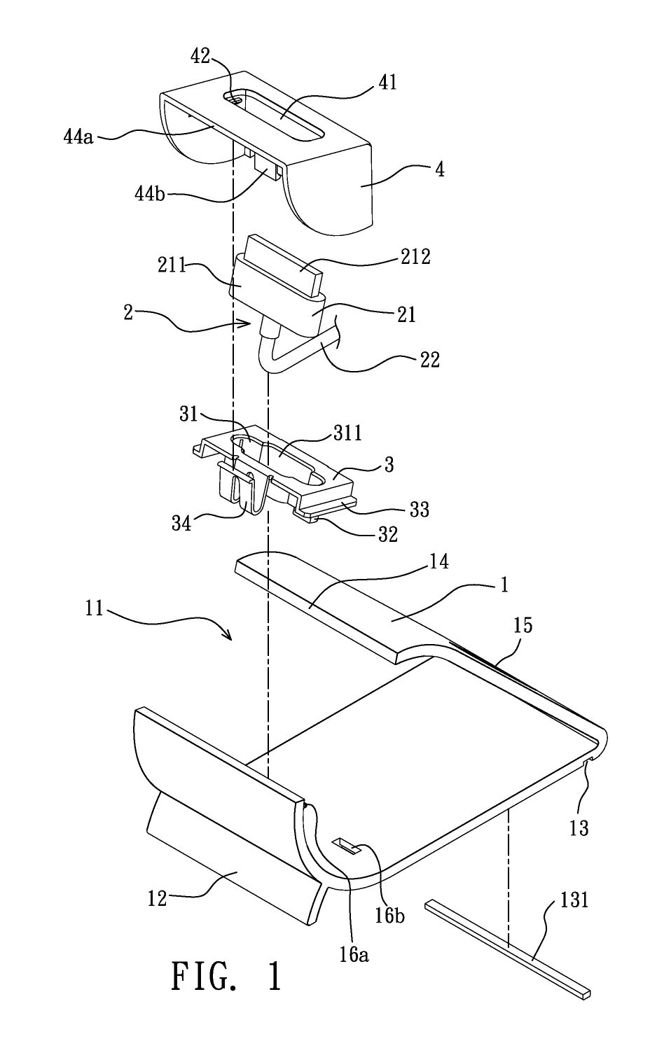

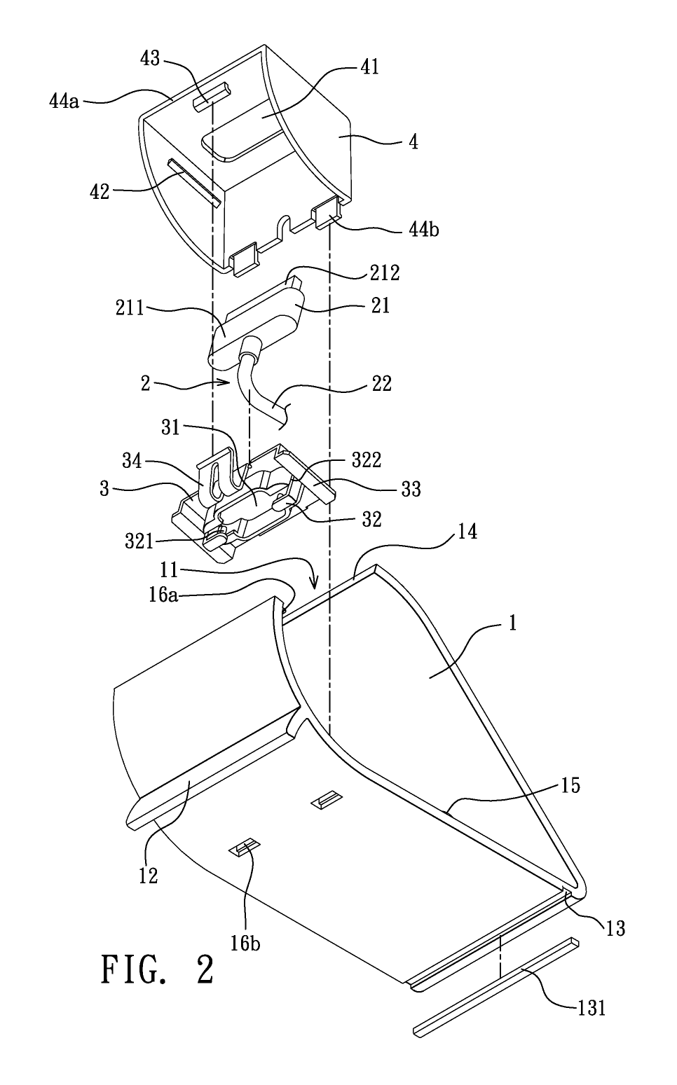

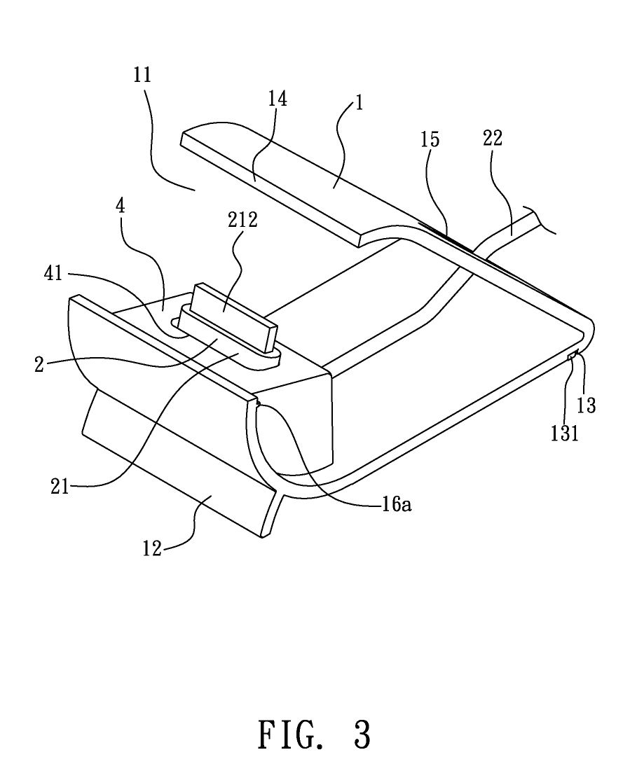

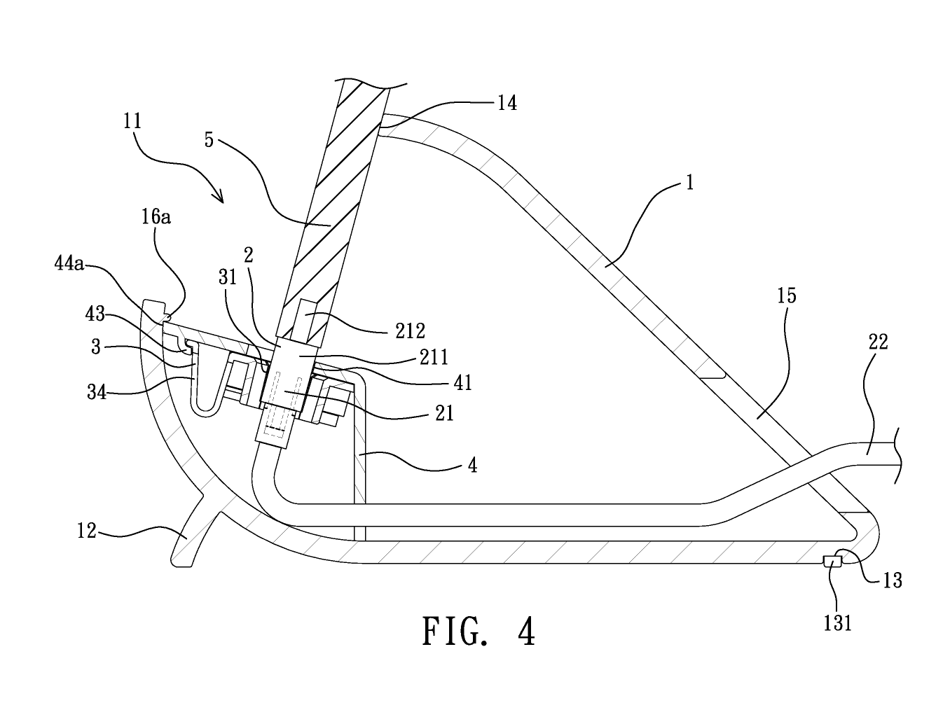

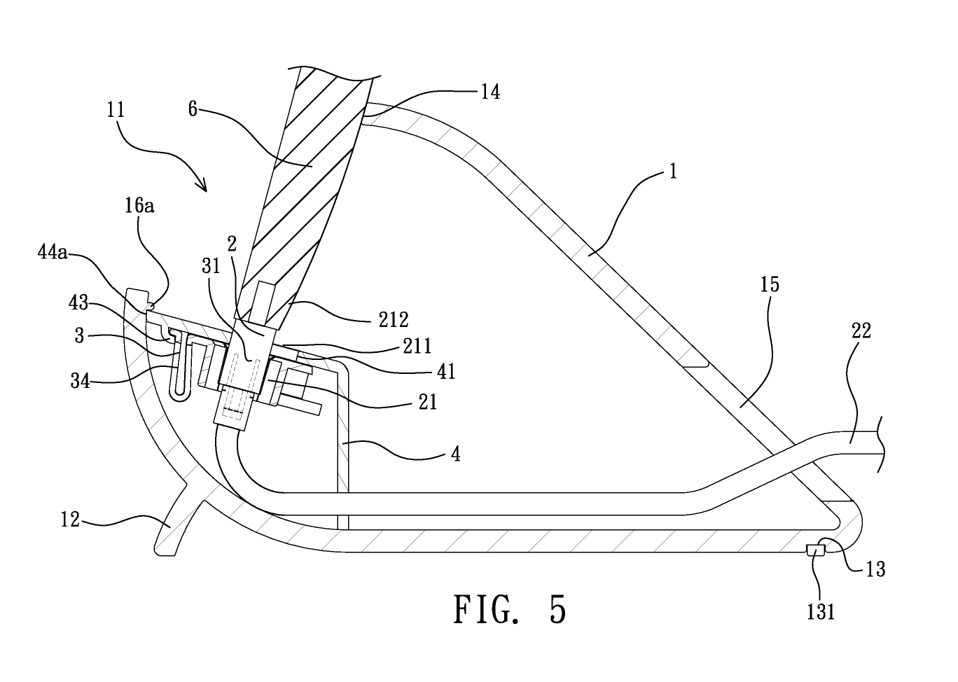

For further disclosing the substantial arts of the present invention, please firstly refer to figures, wherein FIG. 1 is a perspective exploded view showing the docking station, according to the present invention; FIG. 2 is another perspective exploded view showing the docking station taken from another angle, according to the present invention; FIG. 3 is a perspective view showing the assembly of the docking station, according to the present invention; FIG. 4 is a cross sectional view showing the docking station being connected to a hand-held device, according to the present invention; and FIG. 5 is a cross sectional view showing the docking station being connected to another hand-held device, according to the present invention.

As shown from FIG. 1 to FIG. 4, the docking station provided by the present invention comprises a base 1, a slide member 3 and a fasten member 4. When being assembled, the slide member 3 and the fasten member 4 are assembled with a connector 2 of a hand-held device bought by an user, e.g. a tablet PC or intelligent mobile phone, then the fasten member 4 is fastened in the base 1, such that the assembled docking station is provided with functions of charging and data transferring.

The base 1 is, e.g. but not limited to, a hollow wedge-shaped aluminum extruded frame member, an open space is defined at a front opening 11 thereof, at least a support feet 12 and a concave slot 13 are respectively installed at the front and rear sides at the bottom, and the bottom of the concave slot 13 is connected with a non-slip pad 131, so the base 1 is enabled to be stably disposed on a desk surface. The top of the opening 11 is formed with a support wall 14 allowing at least two hand-held devices, e.g. a tablet PC and intelligent mobile phone, to be leaned against. Moreover, the bottom of the opening 11 is installed with an engaging mechanism so the fasten member 4 can be fastened in the opening 11; or the fasten member 4 can be integrally formed in the opening 11 at the front of the base 1, the two mentioned engaging means are both included within the scope of the preset invention. Moreover, the rear of the base 1 is further formed with a cable groove 15 (as shown in FIG. 4) allowing a cable 22 of the connector 2 to pass through.

The connector 2 is a cable related material provide when the hand-held device is purchased, a cable 22 is connected at the rear of a connector plug 21 of the connector 2, wherein the interface of the connector plug 21 is complied with the dock connector specifications of the hand-held device, e.g. the products made by the Apple Inc. including a tablet PC, e.g. the iPad, an intelligent mobile phone, e.g. the iPhone, a media displayer, e.g. the iPod, but the scope of the present invention is not limited to only be used with products made by the Apple Inc.; in actual use, the connector plug 21 can be a USB connector plug with the standard, mini or micro specifications for the purposes of supplying power and transferring data.

One end of the cable 22 is connected to the connector plug 21, and a second connector plug, e.g. a standard USB connector plug (not shown in figures), installed at the other end of the cable 22 passes through the cable groove 15 preset at the rear of the base 1 and connected to a pre-set connection port of a computer such that the hand-held device can be charged or data can be transferred; or the other end of the cable 22 passes through the cable groove 15 preset at the rear of the base 1 and connected to an adapter so after being plugged in a socket of the public power, the hand-held device can be charged.

The slide member 3 is served to be sleeved with the connector plug 21, such that the connector plug 21 can forward/backward slide with the slide member 3. As shown in FIG. 1 and FIG. 2, an accommodation slot 31 is longitudinally formed on the top surface of the slide member 3 for allowing a main body 211 of the connector plug 21 to be inserted therein with a tightly engaging means. Two opposite ends of the bottom of the accommodation slot 31 are installed a pair of block sheets 32, and the top of each block sheet 32 is protrudingly installed with a tenon 321 so as to abut against two bottom ends of the main body 211. Moreover, a trench 322 is formed between two ends of each block sheet 32 and the slide member 3, so each block sheet 32 is equipped with pressing elasticity. If the connector plug 21 is desired to be removed from the accommodation slot 31 of the slide member 3, a user only has to synchronously press the block sheets 32 to enable the pair of tenons 321 to upwardly push the connector plug 21, such that the connector plug 21 can be removed from the slide member 3. Moreover, middle portions of the front and the rear sides of the accommodation slot 31 are respectively installed with hollow parts 311 which are in communication with each other, so a cross-like hole is formed. The dimension of the pair of hollow parts 311 is corresponding to the mentioned second connector plug, e.g. the dimension of a standard USB connector plug, so the second connector plug is enabled to pass through the accommodation slot 31 then protrude out from the cable groove 15.

Moreover, a pair of fins 33 are right/left extended from the slide member 3, and a resilient unit 34 is installed at the front, e.g. but not limited to a U-shaped or V-shaped resilient sheet; in actual use, the resilient unit 34 can also be a spring or a bellow.

The fasten member 4 is a seat member having an opened bottom, a platform defined on the top surface thereof is installed with a slide groove 41 having a width larger than the connector plug 21, the left and right lateral walls of the fasten member 4 are formed with a pair of rails 42 for receiving the left and right fins 33, so a part of the main body 211 of the connector plug 21 sleeved at the top surface of the slide member 3 and a connection part 212 disposed at the top of the main body 211 protrude out of the slide groove 41 and capable of forward/backward sliding. The inner wall of the front end of the fasten member 4 is protrudingly formed with a positioning part 43 (as shown in FIG. 2) for being adjacent to the front of the resilient unit 34; with the stretching elasticity of the resilient unit 34, the connector plug 21 is tightly abutted against the inner side of the slide groove 41 when being in a non-operated state.

As shown in FIG. 1 and FIG. 2, when being assembled, the pair of fins 33 of the slide member 3 are disposed in the rails 42 correspondingly installed in the fasten member 4, and the front of the resilient unit 34 is inserted in the positioning part 43, such that the slide member 3 is integrated with the fasten member 4, and the accommodation slot 31 is disposed below the slide groove 41. Then the second connector plug at the distal end of the connector 2 and the cable 22 are inserted from the slide groove 41 at the top surface of the fasten member 4 and passed through the accommodation slot 31 till the connector plug 21 at the front is inserted and positioned in the accommodation slot 31. As such, the connector plug 21 is enabled to rapidly protrude from the slide groove 41 at the top surface of the fasten member 4 without processes of being fixed through screws.

Lastly, the fasten member 4 and the base 1 are integrated through the engaging mechanism oppositely installed at the front and rear adjacent surfaces of the fasten member 4 and the base 1, then the second connector plug and the cable 22 of the connector 2 protrude from the cable groove 15 at the rear of the base 1, so the docking station as shown in FIG. 3 is assembled. The mentioned engaging mechanism includes a front engaging edge 44a formed at the front of the fasten member 4 for being abutted against a positioning rib 16a formed at the top of the inner bottom wall of the opening 11; and a buckling hook 44b formed at the rear of the fasten member 4 for being buckled with a buckling hole 16b formed at the bottom of the base 1, such that the fasten member 4 and the base 1 can be rapidly integrated without needs of the installation of screws. According to what is mentioned above, the fasten member 4 and the base 1 can also be integrally formed, and the slide member 3 can be installed in the fasten member 4 through a preset hole of the base 1, so the slide member 3 can elastically forward/backward slide in the fasten member 4.

As such, the connector plug 21 can elastically forward/backward slide with the slide member 3 in the slide groove 41 of the fasten member 4, for adjusting the distance between the connector plug 21 and the support wall 14 so as to correspond to hand-held devices having at least two different thicknesses, e.g. a tablet PC and intelligent mobile phone; and a back board of the hand-held device can be adjacent to and leaned against the support wall 14, the connector socket at the bottom of the hand-held device can be stably inserted with the connection part 212 of the connector plug 21.

As shown in FIG. 4, a connector socket at the bottom of a hand-held device 5, e.g. an intelligent mobile phone such as the iPhone, is inserted in the connector plug 21 protruded from the top surface of the fasten member 4, and the back board of the mobile phone 5 is leaned against the support wall 14, at this moment, the connector plug 21 can automatically slide with the slide member 3 in the slide groove 41 of the fasten member 4 for correspondingly to the distance between the connector socket of the mobile phone 5 and the back board, so the mobile phone 5 can be processed with charging or data transferring.

What shall be addressed is that: with the open design of the opening 11 of the base 1 and the fasten member 4, even if the intelligent mobile phone 5 is provided with a protective frame or protective cover by a user, the intelligent mobile phone 5 can still be directly inserted in the connector plug 21, so the disadvantage of conventional docking station in which the size of accommodation groove for receiving a cover board is equal to the external size of a mobile phone, and when the charging operation is desired to be processed, the protective frame or protective cover has to be removed prior to the charging operation.

As shown in FIG. 5, for corresponding to the thickness differences of various hand-held devices, if another hand-held device 6, e.g. a tablet PC such as the iPad, is desired to be processed with charging or data transferring. The user only has to directly insert the connector socket at the bottom of the tablet PC 6 into the connector plug 21 protruded from the top surface of the fasten member 4, and the back board of the tablet PC 6 is leaned against the support wall 14 for adjusting the distance between the connecter plug 21 and the support wall 14, at this moment the connector plug 21 can automatically slide forward with the slide member 3 in the slide groove 41 of the fasten member 4 for corresponding to the distance between the connector socket of the tablet PC 6 and the back board, and the resilient unit 34 is compressed, so the tablet PC 6 is enabled to be processed with charging or data transferring.

When the charging or data transmission is finished, the tablet PC 6 is removed from the connector plug 21 of the docking station, at this moment with the stretching elasticity of the resilient unit 34, the connector plug 21 and the slide member 3 are automatically recovered to the initial locations in the slide groove 41 of the fasten member 4.

Accordingly, as shown in FIG. 4 and FIG. 5, it is obviously to be known that the docking station 1 is capable of accommodating at least two hand-held devices, e.g. the intelligent mobile phone 5 and the tablet PC 6 for processing the charging or data transferring operations, so the docking station provided by the present invention can be used with different hand-held devices, therefore convenience is provided.

As what is mentioned above, the advantages of the present invention are: with the design of the slide member being capable of elastically forward/backward sliding, the docking station can be used with at least two kinds of hand-held devices, e.g. a tablet PC, intelligent mobile phone or media displayer for the purposes of charging or data transferring, so the user does not have to spend unnecessary time and money for additional purchase or managing and storing chargers and transmission cables.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific examples of the embodiments disclosed and that modifications and other embodiments are intended to be included within the scope of the appended claims. Although specific terms are employed herein, they are used in a generic and descriptive sense only and not for purposes of limitation.

What is claimed is:

1. An improved docking station, comprising:
a slide member, the top surface thereof being longitudinally formed with an accommodation slot allowing a connector plug to be positioned and to protrude, two opposite ends of the bottom of said accommodation slot being installed with a pair of block sheets, a pair of fins are left/right extended from said slide member, and a resilient unit is installed at the front; and
a fasten member, a platform defined on the top surface thereof being installed with a slide groove having a width larger than said accommodation slot, the left and right lateral walls thereof being formed with a pair of rails for receiving said left and right fins, the inner wall of the front end of said fasten member being protrudingly formed with a positioning part, so said accommodation slot being enabled to elastically forward/backward slide with said slide member below said slide groove of said fasten member.

2. The improved docking station according to claim 1, wherein the top of each block sheet is protrudingly installed with a tenon, and a trench is installed between two ends of each block sheet and said slide member.

3. The improved docking station according to claim 1, wherein middle portions of the front and the rear sides of said accommodation slot are formed with hollow parts which are in communication with each other, so a cross-like hole is formed.

4. The improved docking station according to claim 1, wherein said resilient unit is a U-shaped or V-shaped resilient sheet, a spring or a bellow.

5. The improved docking station according to claim 1, wherein further including a base, an opening is formed at the front of said base, a support wall is formed at the top of said opening, and said fasten member is disposed in said opening, such that the rear of said slide groove is adjacent to said support wall.

6. The improved docking station according to claim 5, wherein an engaging mechanism is oppositely installed at the front and rear adjacent surfaces of said base and said fasten member, so as to integrate said fasten member and said slide member, said engaging mechanism includes:
a front engaging edge formed at the front of said fasten member for being abutted against a positioning rib formed at the top of the inner bottom wall of said opening; and
a buckling hook formed at the rear of said fasten member for being buckled with a buckling hole formed at the bottom of said base.

7. The improved docking station according to claim 5, wherein a support feet and a concave slot are respectively installed at the front and rear sides at the bottom of said base.

8. The improved docking station according to claim 7, wherein said concave slot is connected with a non-slip pad.

9. The improved docking station according to claim 5, wherein the rear of said base is installed with a cable groove.
